(19) United States
(12) Patent Application Publication
(10) Pub. No.: US 2023/0317668 A1
(43) Pub. Date: Oct. 5, 2023

(54) BARRIERS TO MODULATE UNDERFILL FLOW

(71) Applicants: Ziyin LIN, Chandler, AZ (US); Wei LI, Chandler, AZ (US); Jingyi HUANG, Chandler, AZ (US); Hsin-Yu LI, Chandler, AZ (US)

(72) Inventors: Ziyin LIN, Chandler, AZ (US); Wei LI, Chandler, AZ (US); Jingyi HUANG, Chandler, AZ (US); Hsin-Yu LI, Chandler, AZ (US)

(21) Appl. No.: 17/709,360

(22) Filed: Mar. 30, 2022

(51) Int. Cl. H01L 23/00

(52) U.S. Cl. CPC H01L 24/29; H01L 24/73; H01L 24/32; H01L 24/16; H01L 24/83; H01L 2224/73204; H01L 2224/32225; H01L 2224/16225; H01L 2224/26175; H01L 2224/83007; H01L 2224/8385; H01L 2224/2919; H01L 2224/2929; H01L 2224/29387

(57) ABSTRACT

Embodiments herein relate to systems, apparatuses, or processes that include barriers, which may be referred to as flow stops, to modulate, or control, the speed of flow of an underfill between the substrate and another object on the substrate, for example one or more dies coupled with the substrate. Moderating the speed of flow of the underfill reduces the number of voids in the underfill after curing. Other embodiments may be described and/or claimed.

### FIELD

Embodiments of the present disclosure generally relate to the field of package assemblies, and in particular package assemblies that include underfill.

### BACKGROUND

Continued reduction in end product size of mobile electronic devices such as smart phones and ultrabooks is a driving force for the development of reduced size system in package components.

### BRIEF DESCRIPTION OF THE DRAWINGS

FIG. 1 illustrates a perspective view and a series of top-down views of stages in a legacy manufacturing process for flowing underfill between a substrate and a die.

FIG. 2 illustrates a perspective view and a series of top-down views of stages in a manufacturing process for flowing underfill between a substrate and a die using barriers, in accordance with various embodiments.

FIG. 3 illustrates top-down views of examples of barriers and underfill, in accordance with various embodiments.

FIG. 4A-4C illustrates a series of top-down views of example configurations of barriers on a substrate and proximate to a die, and resulting underfill flow patterns, in accordance with various embodiments.

FIG. 5 illustrates a perspective view and a series of top-down views of stages in a legacy manufacturing process for flowing underfill between the substrate and multiple dies on the substrate where voids are formed within the underfill.

FIGS. 6A-6B illustrate top-down views showing a comparison between a legacy underfill flow through multiple dies and an underfill flow through multiple dies that include barrier, in accordance with various embodiments.

FIG. 7 illustrates a perspective view and a top-down view of multiple dies on a substrate that includes multiple barriers on the substrate proximate to the dies, in accordance with various embodiments.

FIG. 8A-8C illustrate top-down views of various complex die architectures on a substrate and locations of barriers on the substrate, in accordance with various embodiments.

FIG. 9 illustrates an example of a process for forming barriers to modulate underfill flow, in accordance with various embodiments.

FIGS. 10A-10B schematically illustrate a top view of an example die in wafer form and in singulated form, and a cross section side view of a package assembly, in accordance with various embodiments.

FIG. 11 schematically illustrates a computing device, in accordance with embodiments.

### DETAILED DESCRIPTION

Embodiments of the present disclosure may generally relate to systems, apparatus, techniques, and/or processes directed to forming barriers on a substrate to modulate, or control, the speed of flow of an underfill between the substrate and another object on the substrate. For example, the other object may be another substrate, a die, or multiple dies. By moderating the speed of flow of the underfill, voids in the underfill after curing may be prevented or significantly reduced. In embodiments involving a package, a lack of voids in an underfill between substrate and a plurality of dies on the substrate will increase the yield for package manufacturing, and also improve thermomechanical performance of the package by providing better protection of interconnect bumps. In embodiments, the underfill may also be referred to as an epoxy.

In embodiments, barriers, which may also be referred to as flow stops, are placed on the substrate in various locations depending upon a direction and a rate of flow of the underfill during manufacture. In embodiments involving a single die, barriers may be placed on the substrate and on opposite edges of the die to slow the rate of flow of underfill along the edge of the die. This way, the rate of flow of underfill along the edge of the die more evenly matches the rate of flow of the underfill underneath the die. In embodiments that involve multiple dies on the substrate, barriers may be placed at or near gaps between the multiple dies, which may also be referred to as channels, to slow the rate of flow of underfill along the individual edges of the multiple dies. In some embodiments, barriers may be placed between a die and the substrate. In embodiments, the barriers may be of different heights or different dimensions depending on the architecture of the package, the viscosity of the underfill and the flow rate of the underfill.

In embodiments, the barriers may be used to modulate the flow of underfill at an edge or within a die-to-die flow that involves multiple dies. In embodiments, an edge flow along a die could either be slowed or completely blocked by a barrier. In embodiments, this may enable unconventional epoxy dispensing techniques or flow techniques. Examples of unconventional epoxy dispensing techniques may include, but are not limited to, dispensing from opposite sides one or more die, dispensing in a “C” shape where epoxy dispensing occurs along three adjacent edges around the one or more die, or dispensing in an “O” shape where epoxy occurs all around the die. These unconventional techniques may be used to increase package yield, throughput, and reliability. Embodiments described herein may resolve flow voids without underfill materials reformulation or throughput degradation due to a slower epoxy dispense and therefore an increased overall package production time. In addition, embodiments may reduce underfill keep out zone (KOZ), a space around the die allocated to underfill. In addition, embodiments may facilitate a longer dispense path, the length of the underfill dispense, and a lower line density, and underfill dispense weight that may be measured in mg/mm. In embodiments, the material composition of a barrier may be different from the material composition of the underfill. In addition, the barriers may be found at a die edge.

In legacy processes involving underfilling a die that is attached to substrate, the underfill flow speed difference along an edge of a die in comparison to the underfill flow speed in a center area under the die may result in large voids in the die underfill after curing. These voids may result by underfill flow advancing down the edge of the die more rapidly and wrapping around the edges of the die and curing before the flow of the underfill in the center of the die has reached the other edge of the die. The resulting voids, which in some instances may be large, result in package yield loss. In addition, legacy attempts to avoid these voids constrains design rules, such as die size and aspect ratio, interconnect pitch and diameter, and underfill flow properties. In addition, complex die architectures, such as tiled architectures and architectures such as Embedded in Multi-Die Interconnect Bridge (EMIB) architectures that may include dies with very different physical characteristics, create a more complicated flow pattern for underfill and present a higher risk of voids in the underfill.

One legacy implementation may include dispense recipe optimization, for example, reducing the dispense length of the underfill material in order to allow the edge flow and the center flow to reach an endpoint at a similar time. However, this legacy implementation results in a larger epoxy KOZ, due to higher line density and lower throughput.

Another legacy implementation may be to reformulate underfill material with a smaller filler size to reduce center flow resistance and improve the center flow speed so the edge flow and the center flow can fully flow under the die and not result in any voids. However, underfill with a smaller size filler will have a much higher viscosity so that filler loading needs to be reduced to balance the viscosity. For example, smaller filler has larger surface area, leading to higher viscosity. Similarly, higher filler loading has larger surface area and therefore high viscosity. Thus, in legacy implementations, to keep a viscosity the same, filler loading needs to be reduced in order to use smaller fillers. Neither of these legacy implementations may be able to modulate flow of an underfill in a complex multi-tile layout configuration that includes multiple dies.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

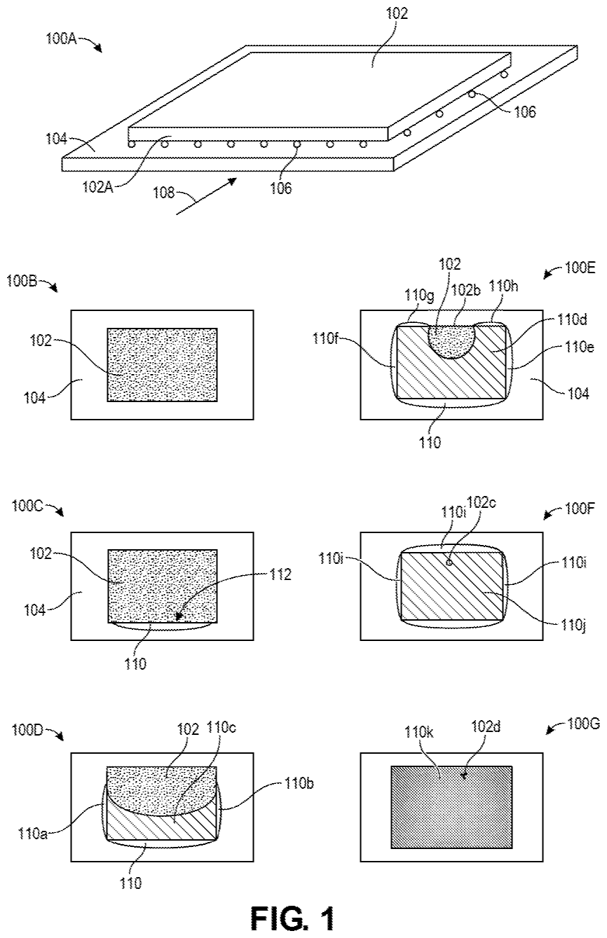

FIG. 1 illustrates a perspective view and a series of top-down views of stages in a legacy manufacturing process for flowing underfill between a substrate and a die. Diagram 100A shows a perspective view of a die 102 that is attached to a substrate 104. The die 102 may be initially coupled with the substrate 104 through a plurality of solder balls 106. In embodiments, the plurality of solder balls 106 may be solder-based interconnects. The solder balls 106 may electrically and/or physically couple the die 102 with the substrate 104. An underfill (not shown) may be dispensed at a side 102A of the die 102 and above the substrate 104 in the direction 108. The side 102A and the direction 108 of the underfill may be referred to as an underfill dispense side, and may also be referred to as a tongue.

Diagram 100B shows a top-down view of a stage in the legacy manufacturing process where die 102 is attached to substrate 104. Diagram 100C shows a top-down view of a stage in a legacy manufacturing process where an underfill 110 is dispensed at a tongue 112 between the die 102 and the substrate 104. The underfill 110 may include an epoxy, and may have a material composition as described further below. Diagram 100D shows a top-down view of a stage in a legacy manufacturing process where the underfill 110 is traveling along the side of and underneath die 102. In particular, underfill 110a, 110b travels down edges of the die 102 at a faster flow rate than the underfill 110c is flowing underneath the die 102.

Diagram 100E shows a top-down view of a stage in the legacy manufacturing process where the underfill 110e, 110f has flowed completely down opposite sides of the die 102, and the underfill 110g, 110h has flowed along the edges of the die 102 around to a back side of the die 102b that is opposite the tongue 112. The underfill 110d underneath the die 102 is flowing at a slower rate, and has not yet fully reach the backside of the die 102b. Diagram 100F shows a top-down view of a stage in the legacy manufacturing process where the underfill 110i has completely flowed around the edge of the die 102, fully encapsulating the area underneath the die 102. Underfill 110j underneath the die 102, because it is traveling more slowly, has not completely filled in underneath the die 102, and as a result a void 102c that does not have any underfill is formed underneath the die 102.

Diagram 100G shows a top-down image of an underflow 110k underneath a die that may be similar to die 102, that includes a flow void 102d underneath the die. The image of diagram 100g may be produced by confocal scanning acoustic microscopy (CSAM). One characteristic of a flow void is that it may occur on an opposite side of the tongue 112 on the die 102. In implementations, a size of the flow void may be large, compared with an interconnect pitch and size, where, for example, if there are one or more interconnects inside a void that do not touch the underfill, the entire package may be rejected. A cause of the flow void is due to the underfill flow at the edge of the die that encounters much lower resistance than the flow beneath and at the center of the die. As a result, the underfill flow at the edge of the die is significantly faster than the underfill flow in the center of the die. In some cases, as shown with respect to FIG. 1, the edge flow closes around at the backside of the tongue prior to the underfill flow below the die reaching the edge, trapping a flow void.

With continuous increases in pitch scaling, the resistance of underfill under the die 102, particularly toward the center, will become increasingly higher, and as a result the flow rate of the underfill will become slower. Therefore, the risk of an underfill flow void will increase for future packaging technologies.

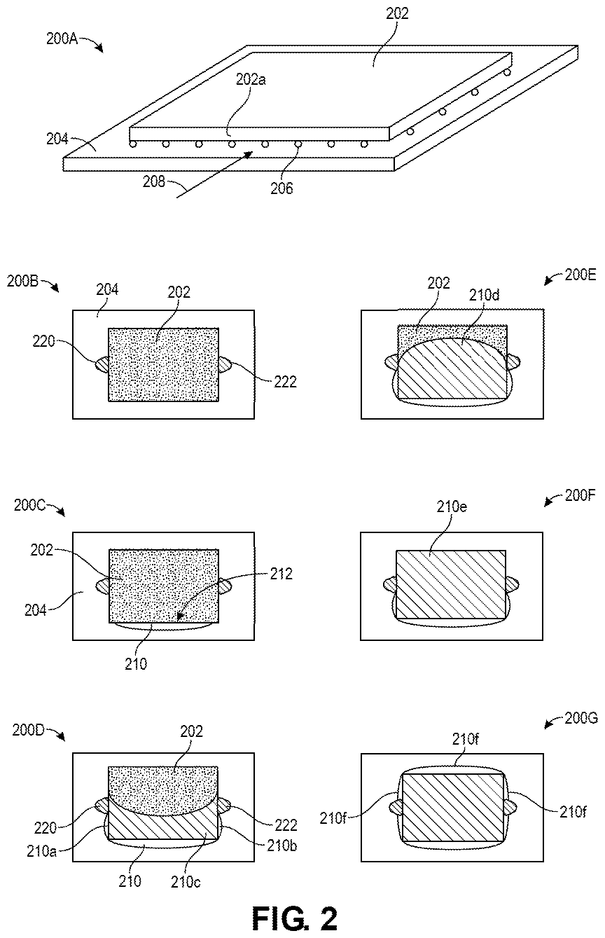

FIG. 2 illustrates a perspective view and a series of top-down views of stages in a manufacturing process for flowing underfill between a substrate and a die using barriers, in accordance with various embodiments. Diagram 200A, which may be similar to diagram 100A of FIG. 1, shows a perspective view of a die 202 that is attached to a substrate 204. The die 202 may be initially coupled with the substrate 204 through a plurality of solder balls 206. The solder balls 206 may electrically and/or physically couple the die 202 with the substrate 204. An underfill (not shown) may be dispensed at a side 202a of the die 202 and above the substrate 204 in the direction 208. The side 202a and the direction 208 of the underfill may be referred to as a tongue.

Diagram 200B shows a top-down view of a stage in the manufacturing process where die 202 is attached to substrate 204. A first barrier 220 may be placed proximate to a first edge of the die 202, and a second barrier 222 may be placed proximate to a second edge of the die 202 opposite the first edge. As shown, barriers 220, 222 may be touching an edge of the die 202. In other embodiments, the barriers 220, 222 may extend underneath the die 202. As shown, barriers 220, 222 may have a cylindrical or a spherical shape. In other embodiments, other shapes may be used.

Diagram 200C shows a top-down view of a stage in a manufacturing process where an underfill 210 is dispensed at a tongue 212 between the die 202 and the substrate 204. The underfill 210 may be similar to underfill 110 of FIG. 1. Diagram 200D shows a top-down view of a stage in a manufacturing process where the underfill 210 is traveling along the side of and underneath die 202. In particular, underfill 210c is flowing underneath the die 202, and underfill 210a, 210b travels down edges of the die 202 until it hits the barriers 220, 222.

Diagram 200E shows a top-down view of a stage in the manufacturing process where the underfill 210d has continued to flow underneath the die 202, while the underfill 210a, 210b along the edges of the die 202 may be stopped by barriers 220, 222. This effectively stops or slows the flow of underfill 210a, 210b, allowing the underfill 210d flow additional time to continue to spread underneath the die 202.

Diagram 200F shows a top-down view of the stage in the manufacturing process where the underfill 210e has flowed completely under the die 202. Diagram 200G shows a top-down view of the stage in the manufacturing process or underfill 210f has flowed from underneath the die 202 out past the edges of the die. As a result, the underfill 210a, 210b of diagram 200D has been blocked from encircling any of the underfill 210e, thus no voids in the underfill are created.

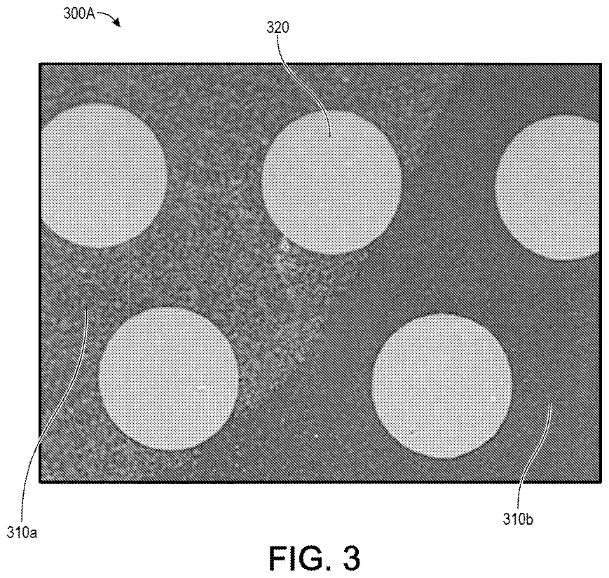

FIG. 3 illustrates top-down views of examples of barriers and underfill, in accordance with various embodiments. Diagram 300a is a top-down image of a plurality of barriers 320, which may also be referred to as flow stops, that are surrounded by a first type of underfill 310a and a second type of underfill 310b. Although the barriers 320 are shown in circular shape, they may take on any geometry, depending upon the structures, for example an edge of the die 202 of FIG. 2 that made deform the shape of a barrier 320.

In embodiments, the barriers 320 may be a direct material that stays on a substrate, such as substrate 204 of FIG. 2, and may stay in contact with the die 202. In embodiments, the barriers 320 may meet reliability requirements. In embodiments, the main polymer chemistry of a barrier 320 may be similar to an underfill material, but with different additives used to control the rheology of the barriers 320. In embodiments, thixotropic agents, nano-sized elastomer particles, and large fillers may be used for barriers 320. In one embodiment, the barriers 320 may contain an average filler size of 4 μm.

In contrast, underfills 310a, 310b may have different compositions, and embodiments may have a 0.4 μm average filler size. In some embodiments, two different types of underfills may be used, for example underfill 310a may contain larger-sized filler, and underfill 310b may contain smaller-sized filler.

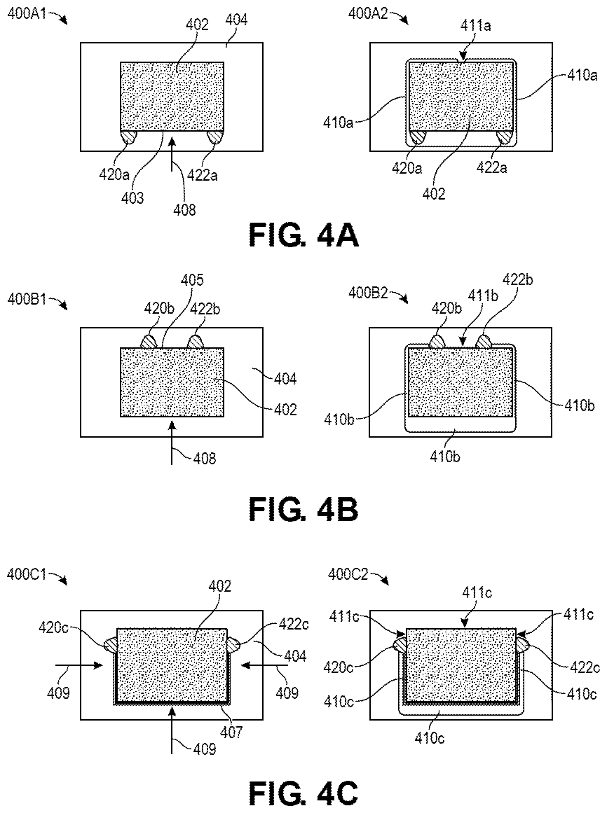

FIG. 4A-4C illustrates a series of top-down views of example configurations of barriers on a substrate and proximate to a die, and resulting underfill flow patterns, in accordance with various embodiments. FIG. 4A shows diagram 400A1 that shows a top-down image, which may be similar to diagram 200B of FIG. 2 that includes a substrate 404 and a die 402 on the substrate 404. A first barrier 420a and a second barrier 422a are placed on die edge 403 and physically coupled with the substrate 404. A direction of underfill material flow 408 is shown. Diagram 400A2 illustrates results of edge flow 410a of the underfill material around the die 402. Note that the edge flow 410a almost completely surrounds the die 402, with a very small gap at 411a at the top. This indicates that the configuration of the barriers 420a, 422a at the bottom edge 403 slows down the edge flow but may not stop it.

FIG. 4B shows diagram 400B1 that shows a top-down image, which may be similar to diagram 200B of FIG. 2 that includes a substrate 404 and a die 402 on the substrate 404. A first barrier 420b and a second barrier 422b are placed on die edge 405 and physically coupled with the substrate 404. A direction of underfill material flow 408 is shown. Diagram 400B2 illustrates results of edge flow 410b of the underfill material around the die 402. Note that the edge flow 410b surrounds the die 402 but stops at the first barrier 420b and the second barrier 422b, leaving a larger gap 411b at the top. This indicates that the configuration of the barriers 420b, 422b at the bottom edge 403 is substantially slowing edge flow, and stops the edge flow at the barriers 420b, 422b.

FIG. 4C shows diagram 400C1 that shows a top-down image, which may be similar to diagram 200B of FIG. 2 that includes a substrate 404 and a die 402 on the substrate 404. A first barrier 420c and a second barrier 422c are placed on opposite edges of the die 402 and are physically coupled with the substrate 404. A direction of underfill material flow 409 is shown. Note that underfill material flow direction 409 is an unconventional underfill disperse pattern as discussed above that comes from three different edges of the die 402, as marked by flow source 407. In embodiments, this type of pattern may provide smaller KOZ and higher throughput, for example a reduced amount of time it takes for the underfill to extend completely under the die 402.

Diagram 400C2 illustrates results of edge flow 410c of the underfill material around the die 402. Note that the edge flow 410c surrounds the die 402 is stopped by the first barrier 420c and the second barrier 422c. The edge areas 411c do not contain any underfill material.

The embodiment examples shown with respect to FIGS. 4A-4C indicate that the effectiveness of barriers on underfill edge flow may depend on a geometry of the barrier, and any momentum of the underfill edge flow. In embodiments, the edge flow may be completely blocked when bigger barriers are used with a lower underfill flow momentum, whereas the edge flow may be slow down with smaller barriers and a higher underfill flow momentum.

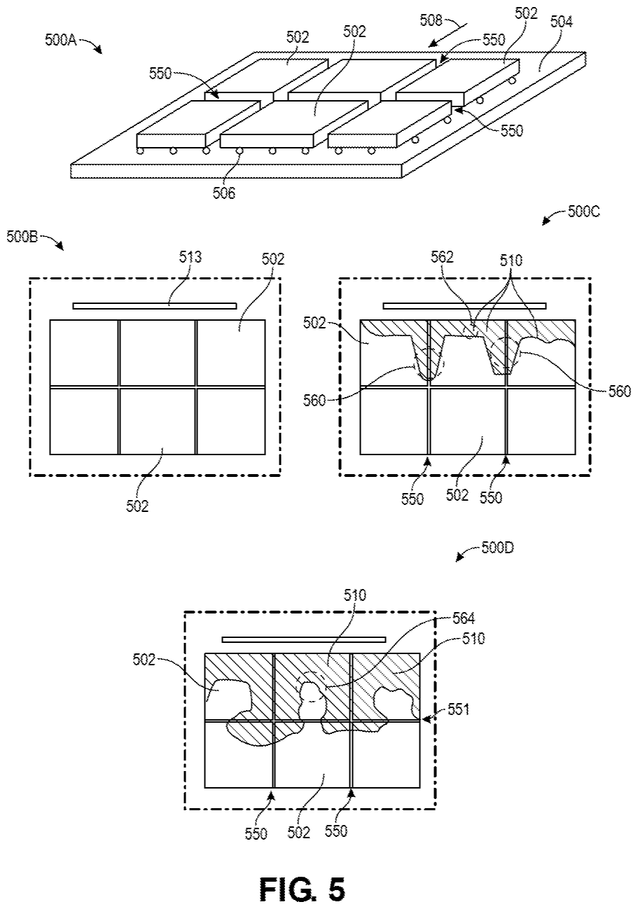

FIG. 5 illustrates a perspective view and a series of top-down views of stages in a legacy manufacturing process for flowing underfill between the substrate and multiple dies on the substrate where voids are formed within the underfill. Diagram 500A, which may be similar to diagram 200A of FIG. 2, shows a perspective view of a plurality of dies 502 attached to a substrate 504. In embodiments, the plurality of dies 502 may be a plurality of tile structures. Note that there are channels 550 that separate each of the plurality of dies 502 from each other.

The plurality of dies 502 may be initially coupled with the substrate 504 through a plurality of solder-based interconnects 506. The solder-based interconnects 506 may electrically and/or physically couple the plurality of dies 502 with the substrate 504. An underfill that is to flow completely under the plurality of dies 502 may be dispensed between the plurality of dies 502 and above the substrate 504 in the direction 508.

Diagram 500B shows a top-down view of the plurality of dies 502 wherein underfill is about to be flowed using the underfill dispenser 513.

Diagram 500C shows a top-down view of the plurality of dies 502 where the underfill 510 has started to flow under the dies 502. Note that in regions 560, the underfill 510 is flowing significantly faster along channels 550, as compared to region 562 that is away from channels 550 and where the underfill 510 is flowing directly underneath one of the dies 502.

Diagram 500D shows a top-down view of the plurality of dies 502 were the underfill 510 has as continue to flow rapidly down channels 550 and across channel 551, to completely surround a void area 564 which underfill 510 has not yet flowed. Because the void area 564 is completely surrounded by underfill 510, no additional underfill 510 will enter the void area 564.

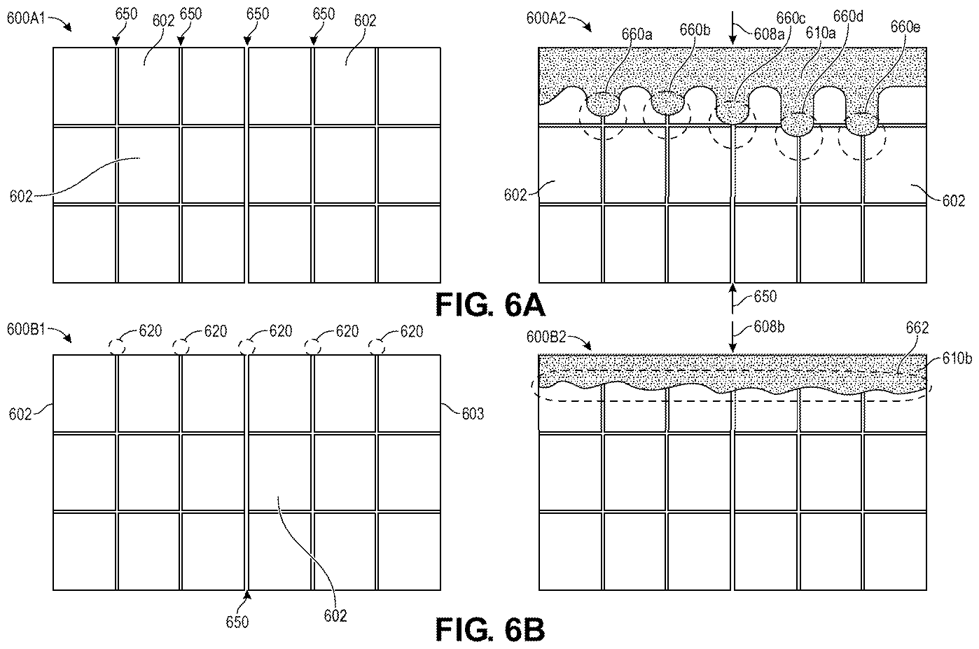

FIGS. 6A-6B illustrate top-down views showing a comparison between a legacy underfill flow through multiple dies and an underfill flow through multiple dies that include barrier, in accordance with various embodiments. FIG. 6A shows a diagram 600A1 that includes a 6×3=18 die that includes tiles 602. The tiles 602 are separated by channels 650. Diagram 600A2 shows underfill 610a that has been flowed in direction 608a over the tiles 602. Note that regions 660a-660e, above channels 650, show that the underfill 610a is flowing at a faster rate down the channels 650 than other areas of the underfill 610a.

FIG. 6B shows diagram 600B1 that includes a 6×3=18 die that includes tiles 602, similar to FIG. 6A. However, a barriers 620, which may also be referred to as a flow stop, is placed at a top of the channels 650. Diagram 600B2 shows the result of an underfill 610b that has been flowed in direction 608b over the tiles 602. Note that the region 662 of the underfill 610b is more evenly distributed as compared to the regions 660a-660e of FIG. 6A.

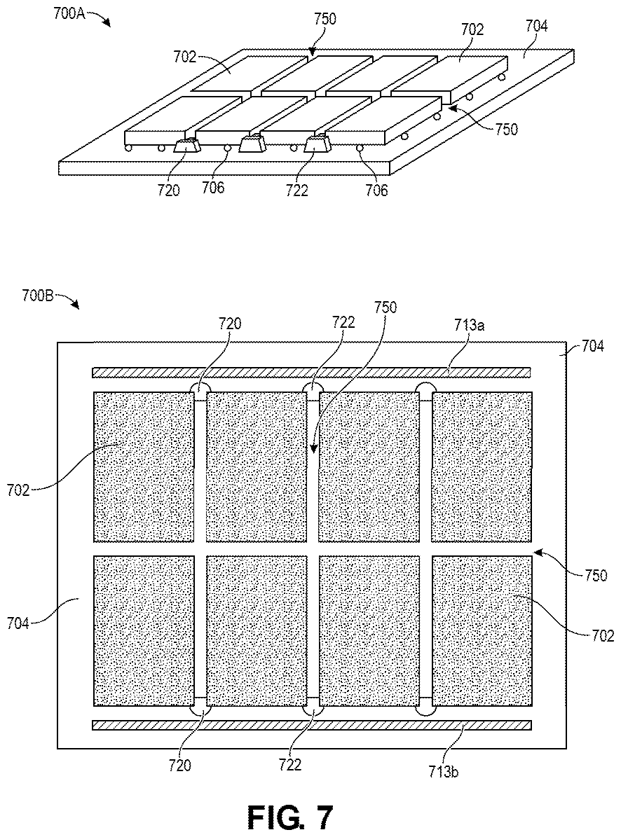

FIG. 7 illustrates a perspective view and a top-down view of multiple dies on a substrate that includes multiple barriers on the substrate proximate to the dies, in accordance with various embodiments. Diagram 700A, which may be similar to diagram 500A of FIG. 5, shows a perspective view of a plurality of dies 702 attached to a substrate 704. In embodiments, the plurality of dies 702 may be a plurality of tile structures. Note that there are channels 750 that separate each of the plurality of dies 702.

The plurality of dies 702 may be initially coupled with the substrate 704 through a plurality of solder balls 706. The solder balls 706 may electrically and/or physically couple the plurality of dies 702 with the substrate 704. An underfill that is to flow completely under the plurality of dies 702 may be dispensed between the plurality of dies 702 and above the substrate 704. Barriers 720, 722 may be placed on the substrate 704, the dies 702, and may be placed at the end of some of the channels 750. Note that the barriers 720, 722, may have different characteristics. For example, a height of barrier 720 above the surface of the dies 702 may be less than a height of barrier 722 above the surface of the substrate 704. In some embodiments, the height of the barrier 722 may exceed a height of the top of the die 702.

Diagram 700B shows a top-down view of diagram 700A, where underfill dispense lines 713a, 713b are shown, that will dispense underfill above the substrate 704 and below the dies 702. The positioning of the barrier 720, 722 may be determined based upon the underfill flow expected from the underfill dispense lines 713a, 713b, in order to slow the speed of the underfill along channels 750. As a result, the flow rate between the underfill dispense lines 713a, 713b will be more uniform as compared to legacy implementations.

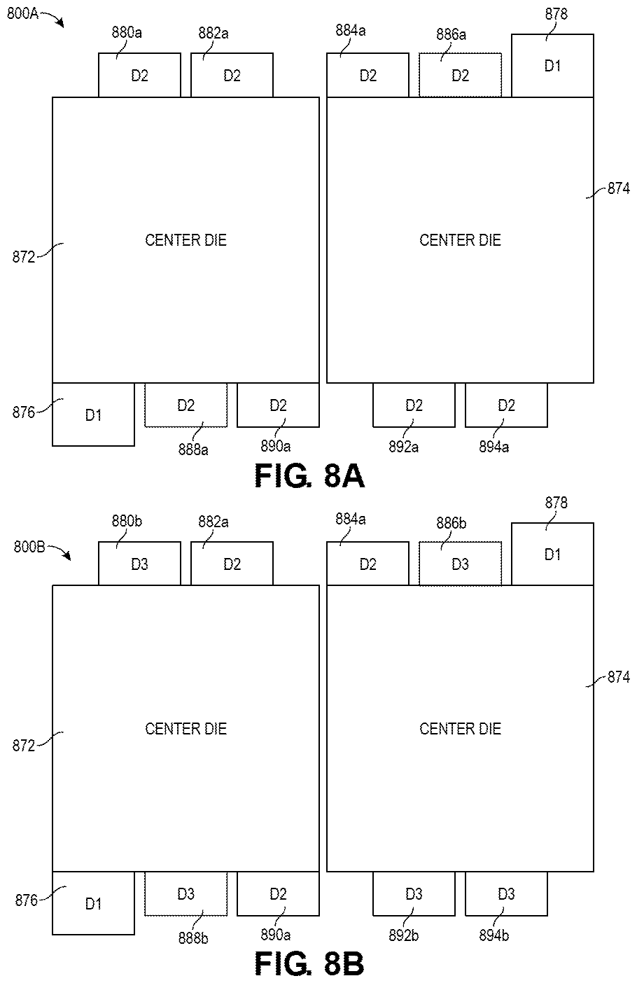

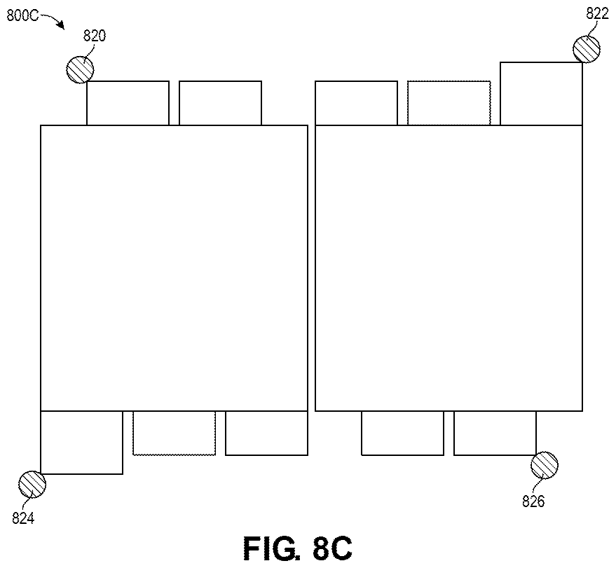

FIG. 8A-8C illustrate top-down views of various complex die architectures on a substrate and locations of barriers on the substrate, in accordance with various embodiments. FIG. 8A includes device 800A that is a complex die architecture which includes two center dies 872, 874, two dies of a first type D1 876, 878, and eight dies of a second type D2 880a, 882a, 884a, 886a, 888a, 890a, 892a, 894a. In embodiments, the center dies 872, 874 may be monolithic silicon dies that are coupled to the various other dies as shown. In embodiments, the D2 dies 880a, 882a, 884a, 886a, 888a, 890a, 892a, 894a may be multilayer packages that have physical characteristics that differ substantially from physical characteristics of the center dies 872, 874. These physical characteristics differences may create substantially different underfill flow dynamics under each die. In legacy implementations, there may be unique underfill processes, or unique underfill recipes that may be developed to provide a void-free underfill for the device 800A.

FIG. 8B includes device 800B, which may be similar to device 800A and includes center dies 872, 874 and D1 dies 876, 878. However, D2 dies 880a, 886a, 888a, 892a, 894a, have been replaced by other types of dies D3 880b, 886b, 888b, 892b, 894b. The D3 dies 880b, 886b, 888b, 892b, 894b may have physical characteristics that differ greatly from the D2 dies 880a, 886a, 888a, 892a, 894a, and therefore device 800B may require a different underfill process or a different underfill recipe that may be required for device 800A in legacy implementations. It should be noted that there are a large number of configurations that might be made based on placements of various D2 dies and D3 dies. Each configuration may require a different underfill process or underfill recipe.

FIG. 8C illustrates device 800C, which may be similar to device 800A or 800B, where, in embodiments, barriers 820, 822, 824, 826 are placed at corners of the device 800C. As a result of this configuration of barriers, during and underfill process, a flow of underfill along the edges of the device 800C will be substantially slowed or stopped. As a result, underfill flow beneath the dies of the device 800C will flow more uniformly across the dies and avoid creating any voids in the underfill. In embodiments, this will be true independent of the configuration of D1, D2, or D3 dies of FIGS. 8A-8B within the device 800C.

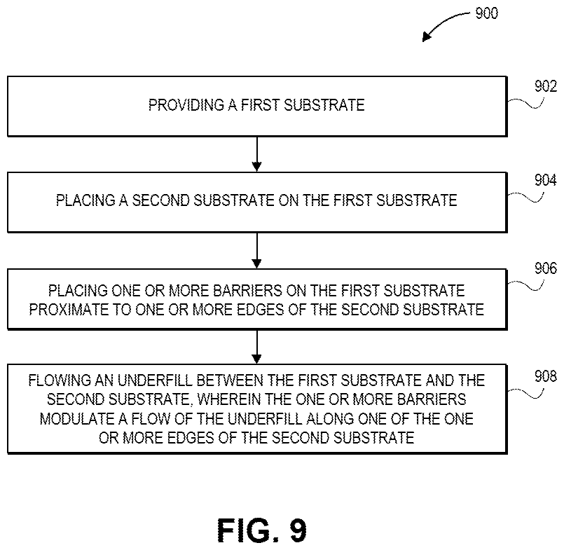

FIG. 9 illustrates an example of a process for forming barriers to modulate underfill flow, in accordance with various embodiments. Process 900 may be performed by one or more elements, techniques, or systems that may be described herein, and in particular with respect to FIGS. 1-8C.

At block 902, the process may include providing a first substrate. In embodiments, the first substrate may be similar to substrate 204 of FIG. 2, substrate 404 of FIGS. 4A-4C, or substrate 704 of FIG. 7.

At block 904, the process may further include placing a second substrate on the first substrate. In embodiments, the second substrate may be similar to die 202 of FIG. 2, die 402 of FIGS. 4A-4C, or dies 702 of FIG. 7.

At block 906, the process may further include placing one or more barriers on the first substrate proximate to one or more edges of the second substrate. In embodiments, the barriers may be similar to barriers 220, 222 of FIG. 2, barriers 320 of FIG. 3, barriers 420a, 422a of FIGS. 4A-4C, barriers 620 of FIG. 6B, barriers 720, 722 of FIG. 7, or barriers 820, 822, 824, 826 of FIG. 8C.

At block 908, the process may further include flowing an underfill between the first substrate and the second substrate, wherein the one or more barriers modulate a flow of the underfill along one of the one or more edges of the second substrate. In embodiments, the underfill may be similar to underfill 210a-210F of FIG. 2.

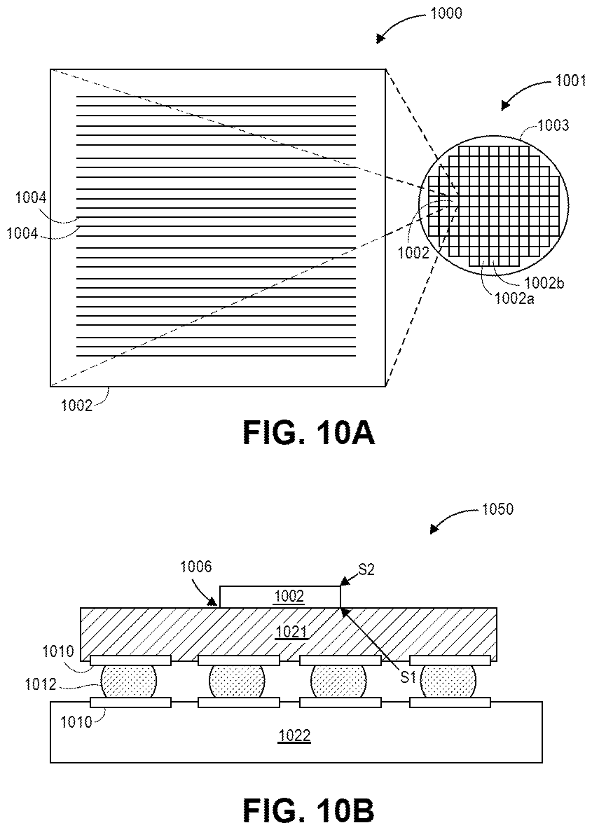

FIGS. 10A-10B schematically illustrate a top view of an example die in wafer form and in singulated form, and a cross section side view of a package assembly, in accordance with various embodiments. FIG. 10A schematically illustrates a top view of an example die 1002 in a wafer form 1001 and in a singulated form 1000, in accordance with some embodiments. In some embodiments, die 1002 may be one of a plurality of dies, e.g., dies 1002, 1002a, 1002b, of a wafer 1003 comprising semiconductor material, e.g., silicon or other suitable material. The plurality of dies, e.g., dies 1002, 1002a, 1002b, may be formed on a surface of wafer 1003. Each of the dies 1002, 1002a, 1002b, may be a repeating unit of a semiconductor product that includes devices as described herein. For example, die 1002 may include circuitry having elements such as capacitors and/or inductors 1004 (e.g., fin structures, nanowires, and the like) that provide a channel pathway for mobile charge carriers in transistor devices. Although one or more capacitors and/or inductors 1004 are depicted in rows that traverse a substantial portion of die 1002, it is to be understood that one or more capacitors and/or inductors 1004 may be configured in any of a wide variety of other suitable arrangements on die 1002 in other embodiments.

After a fabrication process of the device embodied in the dies is complete, wafer 1003 may undergo a singulation process in which each of dies, e.g., die 1002, is separated from one another to provide discrete “chips” of the semiconductor product. Wafer 1003 may be any of a variety of sizes. In some embodiments, wafer 1003 has a diameter ranging from about 25.4 mm to about 450 mm. Wafer 1003 may include other sizes and/or other shapes in other embodiments. According to various embodiments, the one or more capacitors and/or inductors 1004 may be disposed on a semiconductor substrate in wafer form 1001 or singulated form 1000. One or more capacitors and/or inductors 1004 described herein may be incorporated in die 1002 for logic, memory, or combinations thereof. In some embodiments, one or more capacitors and/or inductors 1004 may be part of a system-on-chip (SoC) assembly.

FIG. 10B schematically illustrates a cross-section side view of an integrated circuit (IC) assembly 1050, in accordance with some embodiments. In some embodiments, IC assembly 1050 may include one or more dies, e.g., die 1002, electrically or physically coupled with a package substrate 1021. Die 1002 may include one or more capacitors and/or inductors 1004 as described herein. In some embodiments, package substrate 1021 may be electrically coupled with a circuit board 1022 as is well known to a person of ordinary skill in the art. Die 1002 may represent a discrete product made from a semiconductor material (e.g., silicon) using semiconductor fabrication techniques such as thin film deposition, lithography, etching, and the like. In some embodiments, die 1002 may be, include, or be a part of a processor, memory, SoC or ASIC in some embodiments.

Die 1002 can be attached to package substrate 1021 according to a wide variety of suitable configurations including, for example, being directly coupled with package substrate 1021 in a flip-chip configuration, as depicted. In the flip-chip configuration, an active side 51 of die 1002 including circuitry is attached to a surface of package substrate 1021 using hybrid bonding structures as described herein that may also electrically couple die 1002 with package substrate 1021. Active side 51 of die 1002 may include multi-threshold voltage transistor devices as described herein. An inactive side S2 of die 1002 may be disposed opposite to active side 51.

In some embodiments, package substrate 1021 is an epoxy-based laminate substrate having a core and/or build-up layers such as, for example, an Ajinomoto Build-up Film (ABF) substrate. Package substrate 1021 may include other suitable types of substrates in other embodiments including, for example, substrates formed from glass, ceramic, or semiconductor materials.

Package substrate 1021 may include electrical routing features configured to route electrical signals to or from die 1002. The electrical routing features may include pads or traces (not shown) disposed on one or more surfaces of package substrate 1021 and/or internal routing features (not shown) such as trenches, vias, or other interconnect structures to route electrical signals through package substrate 1021. In some embodiments, package substrate 1021 may include electrical routing features such as pads (not shown) configured to receive the respective die-level interconnect structures 1006 of die 1002.

Circuit board 1022 may be a printed circuit board (PCB) comprising an electrically insulative material such as an epoxy laminate. Circuit board 1022 may include electrically insulating layers composed of materials such as, for example, polytetrafluoroethylene, phenolic cotton paper materials such as Flame Retardant 4 (FR-4), FR-1, cotton paper and epoxy materials such as CEM-1 or CEM-3, or woven glass materials that are laminated together using an epoxy resin prepreg material. Interconnect structures such as traces, trenches, vias may be formed through the electrically insulating layers to route the electrical signals of die 1002 through circuit board 1022. Circuit board 1022 may comprise other suitable materials in other embodiments. In some embodiments, circuit board 1022 is a motherboard as is well known to a person of ordinary skill in the art.

Package-level interconnects such as, for example, solder balls 1012 may be coupled to one or more pads 1010 on package substrate 1021 and/or on circuit board 1022 to form corresponding solder joints that are configured to further route the electrical signals between package substrate 1021 and circuit board 1022. Pads 1010 may comprise any suitable electrically conductive material such as metal including, for example, nickel (Ni), palladium (Pd), gold (Au), silver (Ag), copper (Cu), and combinations thereof. Other suitable techniques to physically and/or electrically couple package substrate 1021 with circuit board 1022 may be used in other embodiments.

IC assembly 1050 may include a wide variety of other suitable configurations in other embodiments including, for example, suitable combinations of flip-chip and/or wire-bonding configurations, interposers, multi-chip package configurations including system-in-package (SiP), and/or package-on-package (PoP) configurations. Other suitable techniques to route electrical signals between die 1002 and other components of IC assembly 1050 may be used in some embodiments.

A person of ordinary skill in the art should recognize that any known semiconductor device fabricated using any known semiconductor process that may benefit from the principles described herein.

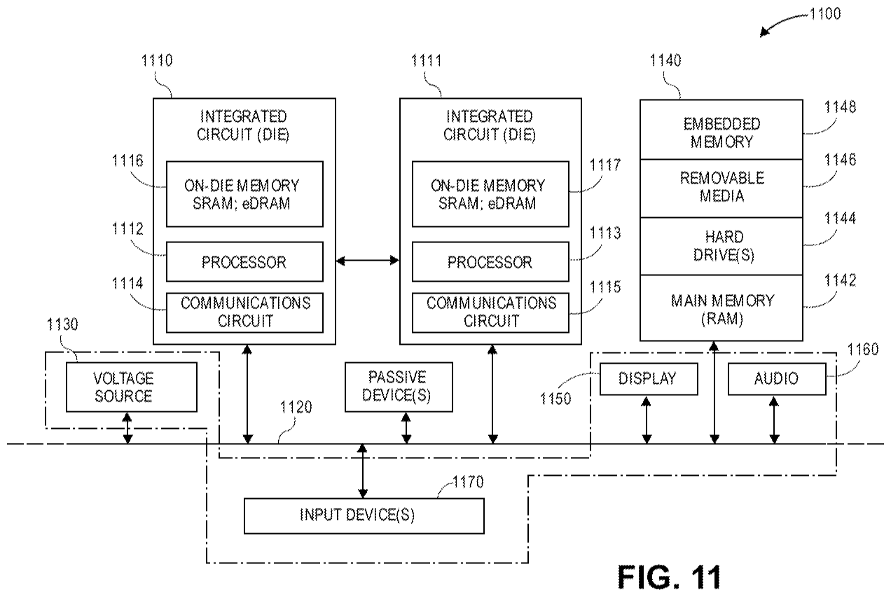

FIG. 11 is a schematic of a computer system 1100, in accordance with an embodiment of the present invention. The computer system 1100 (also referred to as the electronic system 1100) as depicted can embody barriers to modulate underfill flow, according to any of the several disclosed embodiments and their equivalents as set forth in this disclosure. The computer system 1100 may be a mobile device such as a netbook computer. The computer system 1100 may be a mobile device such as a wireless smart phone. The computer system 1100 may be a desktop computer. The computer system 1100 may be a hand-held reader. The computer system 1100 may be a server system. The computer system 1100 may be a supercomputer or high-performance computing system.

In an embodiment, the electronic system 1100 is a computer system that includes a system bus 1120 to electrically couple the various components of the electronic system 1100. The system bus 1120 is a single bus or any combination of busses according to various embodiments. The electronic system 1100 includes a voltage source 1130 that provides power to the integrated circuit 1110. In some embodiments, the voltage source 1130 supplies current to the integrated circuit 1110 through the system bus 1120.

The integrated circuit 1110 is electrically coupled to the system bus 1120 and includes any circuit, or combination of circuits according to an embodiment. In an embodiment, the integrated circuit 1110 includes a processor 1112 that can be of any type. As used herein, the processor 1112 may mean any type of circuit such as, but not limited to, a microprocessor, a microcontroller, a graphics processor, a digital signal processor, or another processor. In an embodiment, the processor 1112 includes, or is coupled with, barriers to modulate underfill flow, as disclosed herein. In an embodiment, SRAM embodiments are found in memory caches of the processor. Other types of circuits that can be included in the integrated circuit 1110 are a custom circuit or an application-specific integrated circuit (ASIC), such as a communications circuit 1114 for use in wireless devices such as cellular telephones, smart phones, pagers, portable computers, two-way radios, and similar electronic systems, or a communications circuit for servers. In an embodiment, the integrated circuit 1110 includes on-die memory 1116 such as static random-access memory (SRAM). In an embodiment, the integrated circuit 1110 includes embedded on-die memory 1116 such as embedded dynamic random-access memory (eDRAM).

In an embodiment, the integrated circuit 1110 is complemented with a subsequent integrated circuit 1111. Useful embodiments include a dual processor 1113 and a dual communications circuit 1115 and dual on-die memory 1117 such as SRAM. In an embodiment, the dual integrated circuit 1110 includes embedded on-die memory 1117 such as eDRAM.

In an embodiment, the electronic system 1100 also includes an external memory 1140 that in turn may include one or more memory elements suitable to the particular application, such as a main memory 1142 in the form of RAM, one or more hard drives 1144, and/or one or more drives that handle removable media 1146, such as diskettes, compact disks (CDs), digital variable disks (DVDs), flash memory drives, and other removable media known in the art. The external memory 1140 may also be embedded memory 1148 such as the first die in a die stack, according to an embodiment.

In an embodiment, the electronic system 1100 also includes a display device 1150, an audio output 1160. In an embodiment, the electronic system 1100 includes an input device such as a controller 1170 that may be a keyboard, mouse, trackball, game controller, microphone, voice-recognition device, or any other input device that inputs information into the electronic system 1100. In an embodiment, an input device 1170 is a camera. In an embodiment, an input device 1170 is a digital sound recorder. In an embodiment, an input device 1170 is a camera and a digital sound recorder.

As shown herein, the integrated circuit 1110 can be implemented in a number of different embodiments, including a package substrate having barriers to modulate underfill flow, according to any of the several disclosed embodiments and their equivalents, an electronic system, a computer system, one or more methods of fabricating an integrated circuit, and one or more methods of fabricating an electronic assembly that includes a package substrate having barriers to modulate underfill flow, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having barriers to modulate underfill flow embodiments and their equivalents. A foundation substrate may be included, as represented by the dashed line of FIG. 11. Passive devices may also be included, as is also depicted in FIG. 11.

### EXAMPLES

The following paragraphs describe examples of various embodiments.

Example 1 is an apparatus comprising: a first substrate; a second substrate on top of the first substrate; a barrier on the first substrate and proximate to the second substrate; an underfill between the first substrate and the second substrate, wherein at least a portion of the underfill is directly physically coupled with the first substrate and with the second substrate; and wherein the underfill is directly physically coupled with at least a portion of the barrier.

Example 2 includes the apparatus of example 1, or of any other example or embodiment described herein, wherein the barrier is between the first substrate and the second substrate, and wherein at least a portion of the barrier is directly physically coupled with the second substrate.

Example 3 includes the apparatus of example 1, or of any other example or embodiment described herein, wherein the underfill includes a selected one or more of: an epoxy resin, a silica filler, and/or additives.

Example 4 includes the apparatus for example 1, or of any other example or embodiment described herein, wherein a material composition of the underfill is different than a material composition of the barrier.

Example 5 includes the apparatus of example 1, or of any other example or embodiment described herein, wherein the barrier includes a plurality of barriers.

Example 6 includes the apparatus of example 5, or of any other example or embodiment described herein, wherein each of the plurality of barriers are separated by the underfill.

Example 7 includes the apparatus of example 5, or of any other example or embodiment described herein, wherein a first of the plurality of barriers is placed at a first edge of the second substrate, and wherein a second of the plurality of barriers is placed at a second edge of the second substrate opposite the first edge.

Example 8 includes the apparatus of example 7, or of any other example or embodiment described herein, wherein a direction of flow of the underfill when the underfill is inserted between the first substrate and the second substrate is from a third edge of the second substrate that is substantially perpendicular to the first edge of the second substrate and to the second edge of the second substrate.

Example 9 includes the apparatus of example 7, or of any other example or embodiment described herein, wherein a third of the plurality of barriers is between the first substrate and the second substrate, and wherein at least a portion of the third of the plurality of barriers is directly physically coupled with the second substrate.

Example 10 includes the apparatus of example 1, or of any other example or embodiment described herein, wherein the second substrate is a portion of a die.

Example 11 includes the apparatus of example 1, or of any other example or embodiment described herein, wherein the barrier slows a portion of the underfill when the underfill is inserted between the first substrate and the second substrate.

Example 12 includes the apparatus of example 11, or of any other example or embodiment described herein, wherein the barrier is positioned on the first substrate based on a direction of flow of the underfill when the underfill is inserted between the first substrate and the second substrate.

Example 13 includes the apparatus of example 1, or of any other example or embodiment described herein, wherein the first substrate and the second substrate are physically coupled by one or more solder connections.

Example 14 includes the apparatus of example 1, or of any other example or embodiment described herein, wherein there are no voids in the underfill between the first substrate and the second substrate.

Example 15 is a system comprising: a first substrate; a plurality of second substrates on the first substrate, wherein each of the plurality of the second substrates are separated from each other by one or more channels; a barrier on the first substrate and proximate to at least one of the one or more channels; an underfill between the first substrate and at least one of the plurality of second substrates, wherein at least a portion of the underfill is directly physically coupled with the first substrate and with the second substrate; and wherein the underfill is directly physically coupled with at least a portion of the barrier.

Example 16 includes the system of example 15, or of any other example or embodiment described herein, wherein the barrier extends across a width of at least one of the one or more channels.

Example 17 includes the system of example 15, or of any other example or embodiment described herein, wherein the barrier is a plurality of barriers.

Example 18 includes the system of example 17, or of any other example or embodiment described herein, wherein at least one of the plurality of barriers is beneath one of the plurality of second substrates.

Example 19 includes the system of example 15, or of any other example or embodiment described herein, wherein at least some of the plurality of second substrates are tiles of a die.

Example 20 includes the system of example 15, or of any other example or embodiment described herein, wherein a flow rate of an underfill below a first of the plurality of second substrates is different than a flow rate of an underfill below a second of the plurality of second substrates.

Example 21 includes the system of example 15, or of any other example or embodiment described herein, wherein a material composition of the underfill is different than a material composition of the barrier.

Example 22 is a method comprising: providing a first substrate; placing a second substrate on the first substrate; placing one or more barriers on the first substrate proximate to one or more edges of the second substrate; and flowing an underfill between the first substrate and the second substrate, wherein the one or more barriers modulate a flow of the underfill along one of the one or more edges of the second substrate.

Example 23 includes the method of example 22, or of any other example or embodiment described herein, wherein providing a second substrate includes providing a plurality of second substrates.

Example 24 includes the method of example 23, or of any other example or embodiment described herein, wherein placing one or more barriers on the first substrate further includes placing one or more barriers on the first substrate in a channel formed between a first one of the plurality of second substrates and a second one of the plurality of second substrates.

Example 25 includes the method of example 22, or of any other example or embodiment described herein, wherein the barrier includes an epoxy.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. An apparatus comprising:
a first substrate;
a second substrate on top of the first substrate;
a barrier on the first substrate and proximate to the second substrate;
an underfill between the first substrate and the second substrate, wherein at least a portion of the underfill is directly physically coupled with the first substrate and with the second substrate; and
wherein the underfill is directly physically coupled with at least a portion of the barrier.

2. The apparatus of claim 1, wherein the barrier is between the first substrate and the second substrate, and wherein at least a portion of the barrier is directly physically coupled with the second substrate.

3. The apparatus of claim 1, wherein the underfill includes a selected one or more of: an epoxy resin, a silica filler, and/or additives.

4. The apparatus of claim 1, wherein a material composition of the underfill is different than a material composition of the barrier.

5. The apparatus of claim 1, wherein the barrier includes a plurality of barriers.

6. The apparatus of claim 5, wherein each of the plurality of barriers are separated by the underfill.

7. The apparatus of claim 5, wherein a first of the plurality of barriers is placed at a first edge of the second substrate, and wherein a second of the plurality of barriers is placed at a second edge of the second substrate opposite the first edge.

8. The apparatus of claim 7, wherein a direction of flow of the underfill when the underfill is inserted between the first substrate and the second substrate is from a third edge of the second substrate that is substantially perpendicular to the first edge of the second substrate and to the second edge of the second substrate.

9. The apparatus of claim 7, wherein a third of the plurality of barriers is between the first substrate and the second substrate, and wherein at least a portion of the third of the plurality of barriers is directly physically coupled with the second substrate.

10. The apparatus of claim 1, wherein the second substrate is a portion of a die.

11. The apparatus of claim 1, wherein the barrier slows a portion of the underfill when the underfill is inserted between the first substrate and the second substrate.

12. The apparatus of claim 11, wherein the barrier is positioned on the first substrate based on a direction of flow of the underfill when the underfill is inserted between the first substrate and the second substrate.

13. The apparatus of claim 1, wherein the first substrate and the second substrate are physically coupled by one or more solder connections.

14. The apparatus of claim 1, wherein there are no voids in the underfill between the first substrate and the second substrate.

15. A system comprising:
a first substrate;
a plurality of second substrates on the first substrate, wherein each of the plurality of the second substrates are separated from each other by one or more channels;
a barrier on the first substrate and proximate to at least one of the one or more channels;
an underfill between the first substrate and at least one of the plurality of second substrates, wherein at least a portion of the underfill is directly physically coupled with the first substrate and with the second substrate; and
wherein the underfill is directly physically coupled with at least a portion of the barrier.

16. The system of claim 15, wherein the barrier extends across a width of at least one of the one or more channels.

17. The system of claim 15, wherein the barrier is a plurality of barriers.

18. The system of claim 17, wherein at least one of the plurality of barriers is beneath one of the plurality of second substrates.

19. The system of claim 15, wherein at least some of the plurality of second substrates are tiles of a die.

20. The system of claim 15, wherein a flow rate of an underfill below a first of the plurality of second substrates is different than a flow rate of an underfill below a second of the plurality of second substrates.

21. The system of claim 15, wherein a material composition of the underfill is different than a material composition of the barrier.

22. A method comprising:
providing a first substrate;
placing a second substrate on the first substrate;
placing one or more barriers on the first substrate proximate to one or more edges of the second substrate; and
flowing an underfill between the first substrate and the second substrate, wherein the one or more barriers modulate a flow of the underfill along one of the one or more edges of the second substrate.

23. The method of claim 22, wherein providing a second substrate includes providing a plurality of second substrates.

24. The method of claim 23, wherein placing one or more barriers on the first substrate further includes placing one or more barriers on the first substrate in a channel formed between a first one of the plurality of second substrates and a second one of the plurality of second substrates.

25. The method of claim 22, wherein the barrier includes an epoxy.
